(19) United States
(12) Patent Application Publication
(10) Pub. No.: US 2023/0269988 A1
(43) Pub. Date: Aug. 24, 2023

(54) ELECTRO-OPTICAL DEVICE AND ELECTRONIC DEVICE

(71) Applicant: SEIKO EPSON CORPORATION, Tokyo (JP)

(72) Inventor: Takumi KODAMA, Chino-shi (JP)

(73) Assignee: SEIKO EPSON CORPORATION, Tokyo (JP)

(21) Appl. No.: 18/171,381

(22) Filed: Feb. 20, 2023

(30) Foreign Application Priority Data
Feb. 21, 2022 (JP) 2022-024998

(51) Int. Cl. H10K 59/35; H10K 59/38; H10K 59/80

(52) U.S. Cl. CPC H10K 59/353; H10K 59/38; H10K 59/876; H10K 59/879

(57) ABSTRACT

An electro-optical device includes a pixel Px1 and a pixel Px2 adjacent in an X direction, each of the pixel (Px1 and the pixel Px2 includes a sub-pixel that emits first color light beam, a sub-pixel emits second color light beam, and a sub-pixel that emits third color light beam, and a first pattern which is an arrangement pattern of a plurality of the sub-pixels included in the pixel Px1 in plan view and a second pattern which is an arrangement pattern of a plurality of the sub-pixels included in the pixel Px2 in plan view are in a relationship of a line symmetry to each other with reference to a virtual line between the pixel Px1 and the pixel Px2.

The present application is based on, and claims priority from JP Application Serial Number 2022-024998, filed Feb. 21, 2022, the disclosure of which is hereby incorporated by reference herein in its entirety.

### BACKGROUND

### 1. Technical Field

The present disclosure relates to an electro-optical device and an electronic device.

### 2. Related Art

In an electro-optical device using, for example, an Organic Light Emitting Diode) (OLED) as a light-emitting element, one pixel includes a plurality of sub-pixels such as three sub-pixels of red, green, and blue in order to realize color display. Each of the three sub-pixels is provided with a color filter (coloring layer) colored in red, green, or blue, and light emitted from the light-emitting element is colored in a corresponding color and emitted. In such a configuration, when a visual field angle varies for each sub-pixel, there is a problem in that variation in color change due to the visual field angle occurs.

Thus, a technique has been proposed, in which in one color among the red, green, and blue sub-pixels constituting one pixel, for example, the number of the blue sub-pixel is two, and the sub-pixels are arranged such that colors of the sub-pixels adjacent to each other in the vertical and horizontal directions are different from each other, and thus a deviation of visual field angle characteristics for each of the red, green, and blue sub-pixels is reduced (see, for example, JP-A-2019-117941).

According to the technique described in JP-A-2019-117941, the deviation of the visual field angle characteristics for each of the red, green, and blue sub-pixels can be reduced, but there is a problem in that the visual field angle itself is narrower.

### SUMMARY

An electro-optical device according to an aspect of the present disclosure includes a first pixel and a second pixel adjacent to the first pixel in a first direction or a second direction, wherein each of the first pixel and the second pixel includes a sub-pixel that emits a first color light beam, a sub-pixel that emits a second color light beam, and a sub-pixel that emits a third color light beam, and a first pattern of the sub-pixels included in the first pixel in plan view and a second pattern of the sub-pixels included in the second pixel in plan view are in a relationship of a line symmetry to each other with reference to a virtual line between the first pixel and the second pixel or in a relationship of being rotated by 180 degrees from each other.

### BRIEF DESCRIPTION OF THE DRAWINGS

FIG. 1 is a perspective view illustrating a configuration of an electro-optical device according to a first embodiment.

FIG. 2 is a block diagram illustrating a configuration of the electro-optical device.

FIG. 3 is a circuit diagram illustrating an electrical configuration of a sub-pixel portion in the electro-optical device.

FIG. 4 is a timing chart illustrating an operation of the electro-optical device.

FIG. 5 is a plan view illustrating an arrangement of light-emitting regions for one pixel in the electro-optical device.

FIG. 6 is a plan view illustrating pixel electrodes in the electro-optical device.

FIG. 7 is a plan view illustrating an arrangement of coloring layers for one pixel in the electro-optical device.

FIG. 8A is a diagram illustrating an array of the light-emitting regions in the electro-optical device.

FIG. 8B is a diagram illustrating an array pattern of the light-emitting regions in the electro-optical device.

FIG. 8C is a plan view illustrating an array pattern of the coloring layers in the electro-optical device.

FIG. 9 is a cross-sectional view of a main portion including the pixel portions in the electro-optical device.

FIG. 10 is a cross-sectional view of a main portion including the pixel portions in the electro-optical device.

FIG. 11 is a view for illustrating improvement of a visual field angle in the electro-optical device.

FIG. 12A is a diagram illustrating an array of light-emitting regions of a first modified example of the first embodiment.

FIG. 12B is a plan view illustrating an array pattern of the light-emitting regions of the first modified example of the first embodiment.

FIG. 13 is a plan view illustrating a second modified example of the first embodiment.

FIG. 14 is a cross-sectional view of a main portion illustrating the second modification example of the first embodiment.

FIG. 15A is a diagram illustrating an array of the light-emitting regions in the electro-optical device according to a second embodiment.

FIG. 15B is a diagram illustrating an array pattern of the light-emitting regions in the electro-optical device.

FIG. 16 is a plan view illustrating a modified example of the second embodiment.

FIG. 17A is a diagram illustrating an array of the light-emitting regions in the electro-optical device according to a third embodiment.

FIG. 17B is a diagram illustrating an array pattern of the light-emitting regions in the electro-optical device.

FIG. 18A is a diagram illustrating an array of the light-emitting regions in the electro-optical device according to a modified example of the third embodiment.

FIG. 18B is a diagram illustrating an array pattern of the light-emitting regions in the electro-optical device.

FIG. 19A is a diagram illustrating an array of the light-emitting regions in the electro-optical device according to a fourth embodiment.

FIG. 19B is a diagram illustrating an array pattern of the light-emitting regions in the electro-optical device.

FIG. 20 is a perspective view illustrating a head-mounted display using an electro-optical device.

FIG. 21 is a diagram illustrating an optical configuration of the head-mounted display.

FIG. 22 is a diagram illustrating an arrangement of sub-pixels in the electro-optical device according to a first comparative example.

FIG. 23 is a view illustrating a visual field angle in the first comparative example.

FIG. 24 is a diagram illustrating an arrangement of sub-pixels in the electro-optical device according to a second comparative example.

### DESCRIPTION OF EXEMPLARY EMBODIMENTS

An electro-optical device according to an embodiment of the present disclosure will be described below with reference to the accompanying drawings. In each of the drawings, dimensions and scale of each part are appropriately different from actual ones. Moreover, the embodiment described below is a suitable specific example, and various technically preferable limitations are applied, but the scope of the disclosure is not limited to these modes unless they are specifically described in the following description as limiting the disclosure.

### First Embodiment

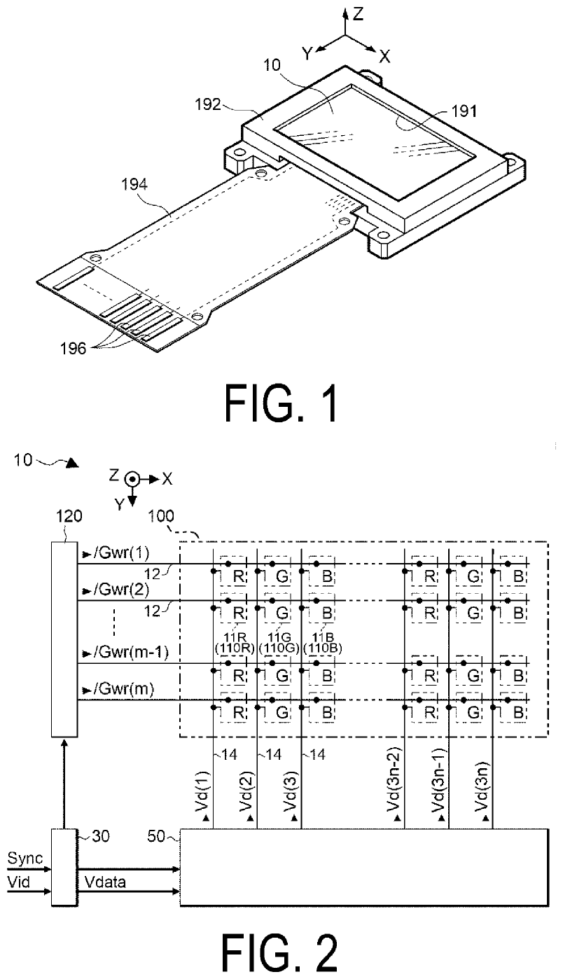

FIG. 1 is a perspective view illustrating an electro-optical device 10. The electro-optical device 10 is a micro display panel that displays an image, for example, in a head-mounted display or the like. The electro-optical device 10 includes a plurality of pixel circuits, a drive circuit that drives the pixel circuits, and the like. The pixel circuits and the drive circuit are integrated into a semiconductor substrate. The semiconductor substrate is typically a silicon substrate, but may be a different semiconductor substrate.

As illustrated in the drawing, the electro-optical device 10 is accommodated in a frame-shaped case 192 including an opening portion 191. One end of a Flexible Printed Circuit (FPC) substrate 194 is coupled to the electro-optical device 10. A plurality of terminals 196 are provided on the other end of the FPC substrate 194. The plurality of terminals 196 are coupled to a high-level device (not illustrated). The high-level device supplies video data and various power supply potentials to the electro-optical device 10 via the FPC substrate 194. The video data is data indicating a video to be displayed by the electro-optical device 10.

In the drawing, an X direction indicates a transverse direction of a display image in the electro-optical device 10, and a Y direction indicates a longitudinal direction of the display image. A two-dimensional plane defined in the X direction and the Y direction is a substrate surface of the semiconductor substrate. A Z direction is perpendicular to the X direction and the Y direction and indicates an emission direction of light emitted from an OLED described below.

FIG. 2 is a diagram illustrating an electrical configuration of the electro-optical device 10. The electro-optical device 10 is substantially divided into a control circuit 30, a data signal output circuit 50, a display region 100, and a scanning line drive circuit 120.

In the display region 100, scanning lines 12 of m rows are provided in the X direction in the drawing, and data lines 14 of (3n) columns are provided in the Y direction to be electrically insulated from each of the scanning lines 12. Each of m and n is an integer equal to or greater than 2.

To distinguish the rows from each other in the scanning lines 12, the rows may be referred to as first, second, . . . , (m−1)-th, and m-th rows in order from the top in the drawing. Note that to generally explain the scanning line 12 without specifying a row, the scanning line 12 may be denoted as an i-th row by using an integer i of 1 or more and m or less.

To distinguish the columns from each other in the data lines 14, the columns may be referred to as first, second, third, . . . , (3n−2)-th, (3n−1)-th, and (3n)-th columns in order from the left in the drawing. The data lines 14 are grouped every three columns. To generalize and describe a group, when an integer j of 1 or more and n or less, total of three columns of the data lines 14 of (3j−2)-th, (3j−1)-th, and (3j)-th columns belong to a j-th group, as counting from the left.

Sub-pixels 11R, 11G, and 11B are provided corresponding to the scanning lines 12 arrayed in the m rows and the data lines 14 arrayed in the (3n) columns. Specifically, the sub-pixel 11R is provided corresponding to an intersection between the scanning line 12 of the i-th row and the data line 14 of the (3j−2)-th column. The sub-pixel 11G is provided corresponding to an intersection between the scanning line 12 of the i-th row and the data line 14 of the (3j−1)-th column. The sub-pixel 11B is provided corresponding to an intersection between the scanning line 12 of the i-th row and the data line 14 of the (3j)-th column.

As will be described later, the sub-pixel 11R includes a light-emitting element that emits light including a red component, the sub-pixel 11G includes a light-emitting element that emits light including a green component, and the sub-pixel 11B includes a light-emitting element that emits light including a blue component. One color is expressed by additive color mixing of light emitted from the sub-pixels 11R, 11B and 11G.

The control circuit 30 controls each portion based on video data Vid and a synchronization signal Sync supplied from the host device, which is not illustrated. Specifically, the control circuit 30 generates various control signals to control each portion.

The video data Vid designates a gray scale level of
a pixel to be displayed by, for example, 8 bits. The synchronization signal Sync includes a vertical synchronization signal that instructs a start of vertical scanning of the video data Vid, a horizontal synchronization signal that instructs a start of horizontal scanning, and a dot clock signal that indicates a timing of one pixel of the video data.

Pixels of an image to be displayed in the present embodiment and pixel portions 110 in the display region 100 correspond one-to-one with each other.

Characteristics of a luminance at a gray scale level indicated by video data Vid supplied from the host device and characteristics of a luminance in the OLED included in the pixel portion 110 do not necessarily coincide with each other. Thus, to make the OLED emit light at a luminance corresponding to the gray scale level indicated by the video data Vid, the control circuit 30 up-converts 8 bits of the video data Vid into, for example, 10 bits and outputs it as video data Vdata. Thus, the 10-bit video data Vdata is data corresponding to the gray scale level designated by the video data Vid.

A look-up table in which a correspondence relationship between the 8 bits of the video data Vid which is an input and the 10 bits of the video data Vdata which is an output is stored in advance is used in the up-conversion.

The scanning line drive circuit 120 is a circuit for driving the pixel portions 110 arrayed in m rows and (3n) columns for each row corresponding to control by the control circuit 30. For example, the scanning line drive circuit 120 supplies scanning signals /Gwr(1), /Gwr(2), . . . , /Gwr(m−1), /Gwr(m) to the scanning lines 12 of first, second, third, . . . , (m−1)-th, and m-th rows in order. To generalize, the scanning signal supplied to the scanning line 12 in the i-th row is denoted as/Gwr(i).

The data signal output circuit 50 is a circuit that outputs a data signal to the pixel portions 110 located in a row selected by the scanning line drive circuit 120 via the data line 14 corresponding to the control of the control circuit 30. The data signal is a voltage signal that converts the 10-bit video data Vdata into an analog type. In other words, the data signal output circuit 50 converts video data Vdata of one row corresponding to the pixel portions 110 of first to (3n)-th columns in the selected row into an analog type and outputs the analog type data to the data lines 14 of the first to (3n)-th columns in this order.

In the drawings, the data signals output to the data lines 14 of the first, second, third, . . . , (3n−2)-th, (3n−1)-th, and (3n)-th columns are referred to as Vd(1), vd(2), vd(3), . . . , vd(3n−2), vd(3n−1), and vd(3n). To generalize, a potential of the data line 14 of a j-th column is denoted as Vd(j).

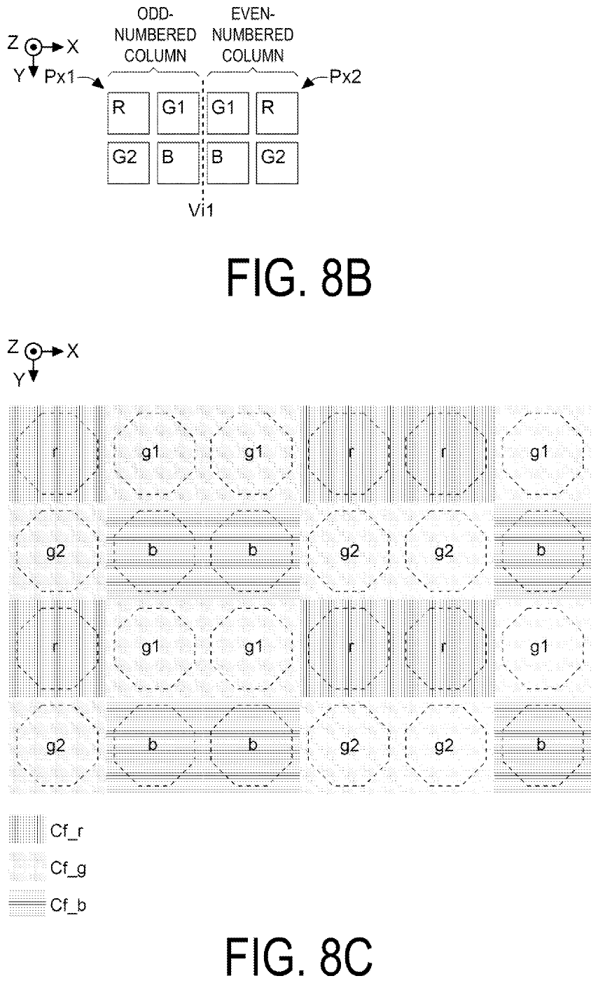

Note that the array of the sub-pixels 11R, 11G, and 11B illustrated in FIG. 2 is only an electrical point of view, and in reality, they are arrayed as illustrated in FIG. 8A which will be described later.

The electrical configurations in the sub-pixels 11R, 11G, and 11B are identical to each other.

Thus, the electrical configurations in the sub-pixels 11R, 11G, and 11B will be described with the sub-pixel 11R corresponding to the i-th row and (3j−2)-th column as a representative.

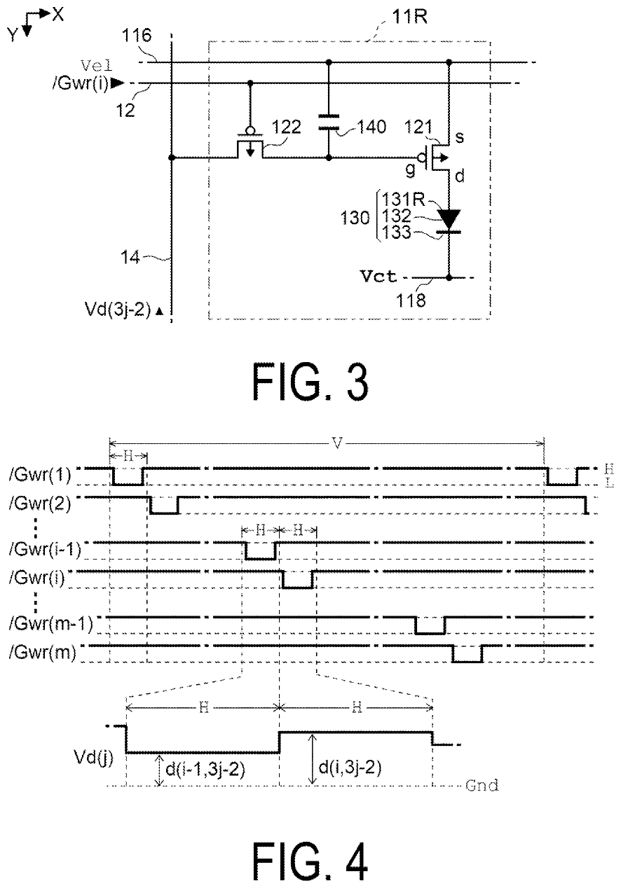

FIG. 3 is a circuit diagram illustrating the electrical configuration in the sub-pixel 11R. As illustrated in the drawing, the sub-pixel 11R includes P-channel MOS type transistors 121 and 122, an OLED 130, and a capacitive element 140 from the electrical point of view.

In the description of the sub-pixel 11R, the “electrical point of view” is used when a plurality of elements constituting the sub-pixel 11R and a coupling relationship between the plurality of elements are referred to. Since the sub-pixel 11R includes elements that do not contribute to the electrical coupling relationship from a mechanical or physical point of view, such an expression is used.

The OLED 130 is an example of a light-emitting element in which a light-emitting layer 132 is sandwiched between a pixel electrode 131R and a common electrode 133. The pixel electrode 131R functions as an anode, and the common electrode 133 functions as a cathode. In the OLED 130, when a current flows from the anode to the cathode, holes injected from the anode and electrons injected from the cathode are recombined in the light-emitting layer 132 to generate excitons, and white light is generated.

The generated white light resonates in an optical resonator configured of a reflective electrode omitted in FIG. 3 and a semi-reflective and semi-transmissive layer and is emitted at a resonance wavelength set corresponding to a red color in a case of the sub-pixel 11R. A coloring layer corresponding to the red color is provided on the emission side of the light from the optical resonator. Thus, the emitted light from the OLED 130 is visually recognized by an observer through the optical resonator and the coloring layer.

In a case of the sub-pixel 11G, the generated white light is emitted at a resonance wavelength set corresponding to a green color and is visually recognized by the observer through the coloring layer corresponding to the green color, and in a case of the sub-pixel 11B, the generated white light is emitted at a resonance wavelength set corresponding to a blue color and is visually recognized by the observer through the coloring layer corresponding to the blue color.

In the transistor 121 of the sub-pixel 11R in the i-th row and the (3j−2)-th column, a gate node g is coupled to a drain node of the transistor 122, a source node is coupled to a feed line 116 of a voltage Vel, and a drain node is coupled to the pixel electrode 131R which is an anode of the OLED 130.

In the transistor 122 of the sub-pixel 11R in the i-th row and the (3j−2)-th column, a gate node is coupled to the scanning line 12 of the i-th row, and a source node is coupled to the data line 14 of the (3j−2)-th column. The common electrode 133 which functions as a cathode of the OLED 130 is coupled to a feed line 118 of a voltage Vct. Further, since the electro-optical device 10 is formed on a silicon substrate, a substrate potential of each of the transistors 121 and 122 is set to a potential corresponding to, for example, the voltage Vel.

The sub-pixel 11R illustrated in FIG. 3 is common to the sub-pixels 11G and 11B from the electrical point of view, but the sub-pixels 11R, 11G, and 11B are different from each other from a structural point of view.

For example, the pixel electrode of the sub-pixel 11G has a different shape from a shape of the pixel electrode 131R of the sub-pixel 11R. Thus, the pixel electrode of the sub-pixel 11G is denoted by 131G, and the pixel electrode of the sub-pixel 11B is denoted by 131B.

FIG. 4 is a timing chart for describing an operation of the electro-optical device 10.

In the electro-optical device 10, the scanning lines 12 of m rows are scanned one by one in the order of first, second, third, . . . , m-th rows during a period of a frame (V). Specifically, as illustrated in the drawing, the scanning signals /Gwr(1), /Gwr(2), . . . , /Gwr(m−1), and/Gwr (m) successively and exclusively reach an L level for each horizontal scanning period (H) by the scanning line drive circuit 120.

In the present embodiment, a period during which the adjacent scanning signals among the scanning signals /Gwr(1) to /Gwr(m) reach the L level is temporally isolated. Specifically, after the scanning signal /Gwr(i−1) changes from the L level to a H level, the next scanning signal /Gwr(i) reaches the L level after a period of time. This period corresponds to a horizontal return period.

In the present description, the period of one frame (V) refers to a period required to display one frame of an image designated by the video data Vid. In a case in which a length of the period of one frame (V) is the same as a vertical synchronization period, for example, when a frequency of a vertical synchronization signal included in the synchronization signal Sync is 60 Hz, it is 16.7 milliseconds which corresponds to one cycle of the vertical synchronization signal. In addition, the horizontal scanning period (H) is an interval of time in which the scanning signals /Gwr(1) to /Gwr(m) reach the L level in order, but in the drawing, for convenience, a start timing of the horizontal scanning period (H) is approximately a center of the horizontal return period.

When a certain scanning signal among the scanning signals /Gwr(1) to /Gwr(m), for example, the scanning signal /Gwr(i) supplied to the scanning line 12 in the i-th row reaches the L level, the transistor 122 in the sub-pixel 11R of the i-th row and the (3j−2)-th column, speaking of the (3j−2)-th column, is in an ON state. Thus, the gate node g of the transistor 121 in the sub-pixel 11R is electrically coupled to the data line 14 of the (3j−2)-th column.

In the present description, the “On state” of the transistor means that a distance between the source node and the drain node in the transistor is electrically closed to be in a low impedance state. Also, an “OFF state” of the transistor means that the distance between the source node and the drain node electrically opens to be in a high impedance state.

Also, in the description, “electrically coupled” or simply “coupled” means a state in which two or more elements are directly or indirectly coupled or coupled. “Electrically non-coupled” or simply “non-coupled” means a state in which the two or more elements are not directly or indirectly coupled or coupled.

In the horizontal scanning period (H) in which the scanning signal /Gwr(i) reaches the L level, the data signal output circuit 50 converts the gray scale levels of sub-pixels in the i-th row and first column to the i-th row and (3n)-th column indicated by the video data Vdata into analog potentials Vd(1) to Vd(n), and outputs the analog potentials Vd(1) to Vd(n) to the data signals 14 in the first to (3n)-th columns as data signals. Speaking of the (3j−2)-th column, the data signal output circuit 50 converts the gray scale level d (i, 3j−2) of the pixel in the i-th row and (3j−2)-th column into the potential Vd(j) of the analog signal, and outputs the potential Vd(j) to the data line 14 in the (3j−2)-th column.

In the horizontal scanning period (H) in which the scanning signal /Gwr(i−1) one line before the scanning signal /Gwr(i) reaches the L level, the data signal output circuit 50 converts the gray scale level d(i−1, 3j−2) of the sub-pixel in the (i−1)-th row and (3j−2)-th column to the potential Vd(3j−2) of the analog signal, and outputs the potential Vd(3j−2) to the data signal 14 in the (3j−2)-th column as a data signal.

The data signal of the potential Vd (3j−2) is applied to the gate node g of the transistor 121 in the sub-pixel 11R in the i-th row and (3j−2)-th column via the data line 14 in the (3j−2)-th column, and the potential Vd (3j−2) is retained by the capacitive element 140. Thus, the transistor 121 causes a current corresponding to a voltage between the gate node and the source node to flow to the OLED 130.

Even when the scanning signal Gwr(i) reaches a H level and the transistor 122 is in the OFF state, the potential Vd(3j−2) is retained by the capacitive element 140, and thus the current continues to flow in the OLED 130. Thus, in the sub-pixel 11R in the i-th row and (3j−2)-th column, the OLED 130 continues to emit light with a voltage retained by the capacitive element 140, that is, a luminance corresponding to the gray scale level until the period of one frame (V) elapses and the transistor 122 is turned on again and the voltage of the data signal is applied again.

Although the sub-pixel 11R of the i-th row and (3j−2)-th column has been described here, the OLED 130 other than the (3j−2)-th column in the i-th row also emits light at the luminance indicated by the video data Vdata.

Also, each OLED 130 of the sub-pixels 11R, 11G, and 11B other than the i-th row also emits light with the luminance indicated by the video data Vdata by the scanning signals /Gwr(1) to /Gwr(m) reaching the L level in order.

Thus, in the electro-optical device 10, during the period of one frame (V), each OLED 130 in all of the sub-pixels 11R, 11G, and 11B from the first row and first column to the m-th row and (3n)-th column emits light at the luminance indicated by the video data Vdata, and thus an image of one frame is displayed.

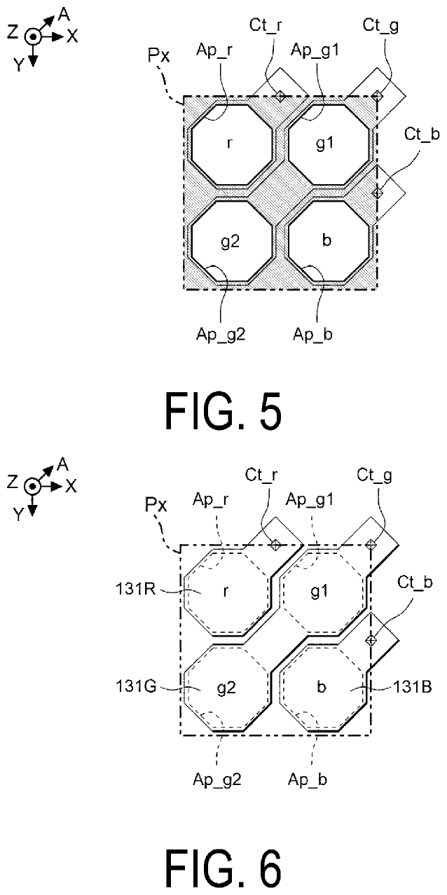

FIG. 5 is a plan view illustrating an array pattern serving as a base in the light-emitting region of the display region 100, and FIG. 6 is a plan view illustrating shapes of the pixel electrodes 131R, 131G, and 131B.

In these drawings, Px having a frame shape is a pixel that is an expression unit of one color. In the pixel Px, light-emitting regions r, g1, g2, and b are arrayed in two rows and two columns, and one color is expressed by the additive color mixing due to emitted light from these light-emitting regions.

The light-emitting region r is a region in the pixel electrode 131R illustrated in FIG. 6 which is in contact with the light-emitting layer 132. The light-emitting regions g1 and g2 are regions in the pixel electrode 131G which are in contact with the light-emitting layer 132. The light-emitting region b is a region in the pixel electrode 131B which is in contact with the light-emitting layer 132.

The light-emitting regions r, g1, g2, and b are defined by opening portions Ap_r, Ap_g1, Ap_g2, and Ap_b of a separation layer in order. The opening portions Ap_r, Ap_g1, Ap_g2, and Ap_b are formed by patterning the separation layer having insulating properties provided to cover the pixel electrodes 131R, 131G, and 131B as described below.

The reason that the green light-emitting region is the two regions of g1 and g2 while the light-emitting region r or the light-emitting region b is one region is that, for example, green has the highest visibility among red, green, and blue, and thus the life of green is ensured.

For convenience of explanation, in FIG. 5 and FIG. 6, a direction in which the X direction is rotated counterclockwise by 45 degrees is referred to as an A direction.

In FIG. 6, the pixel electrode 131R has a shape in which an octagon and a rectangle are connected to each other in plan view. Specifically, one side of a rectangular region and one side of an octagonal region in the pixel electrode 131R have substantially the same length, and the rectangle is located in the A direction with respect to the octagon. In such a pixel electrode 131R, an octagonal opening portion Ap_r smaller than the octagon is provided in the octagonal region, and a contact hole Ct_r is provided in the rectangular region. The contact hole Ct_r is a region for being coupled to the lower wiring line in the pixel electrode 131R. The lower wiring line is further electrically coupled to the drain node of the transistor 121 in the sub-pixel 11R via a plurality of elements.

The pixel electrode 131G has a shape in which two pixel electrodes 131R are connected in the A direction in plan view. In such a pixel electrode 131G, an octagonal opening portion Ap_g1 smaller than the octagon is provided in the octagonal region located in the upper right in the drawing among the two octagons. In the pixel electrode 131G, an octagonal opening portion Ap_g2 smaller than the octagon is provided in the octagonal region located in the lower left among the two octagons.

Further, in the pixel electrode 131G, a contact hole Ct_g is provided in the rectangular region located in the A direction with respect to the opening portion Ap_g1.

The contact hole Ct_g is a region for being coupled to the lower wiring line in the pixel electrode 131G. The lower wiring line is further electrically coupled to the drain node of the transistor 121 in the sub-pixel 11G via a plurality of elements.

The pixel electrode 131B has substantially the same shape as the pixel electrode 131R in plan view. In such a pixel electrode 131B, an octagonal opening portion Ap_b smaller than the octagon is provided in the octagonal region, and a contact hole Ct_b is provided in the rectangular region. The contact hole Ct_b is a coupling region of the lower wiring line in the pixel electrode 131B, and the lower wiring line is further electrically coupled to the drain node of the transistor 121 in the pixel portion 110B via a plurality of elements.

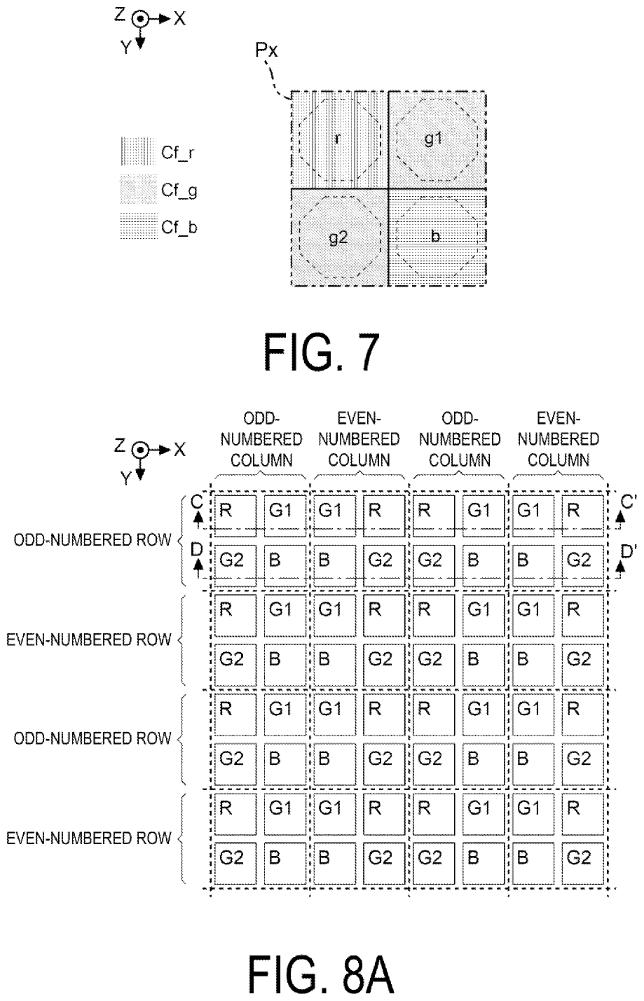

FIG. 7 is a plan view illustrating an array pattern serving as a base in the coloring layer. As illustrated in the drawing, a coloring layer Cf_r corresponding to red is provided to cover the light-emitting region r in plan view, and a coloring layer Cf_g corresponding to green is provided to cover the light-emitting regions g1 and g2. A coloring layer Cf_b corresponding to blue is provided to cover the light-emitting region b.

Emitted light from the light-emitting regions r, g1, g2, and b is visually recognized by a user. That is, in plan view, the light-emitting region r is visually recognized as a red sub-pixel, each of the light-emitting regions g1 and g2 is visually recognized as a green sub-pixel, and the light-emitting region b is visually recognized as a blue sub-pixel. Thus, in plan view, the light-emitting region r can be treated as the red sub-pixel, each of the light-emitting regions g1 and g2 can be treated as the green sub-pixel, and the light-emitting region b can be treated as the blue sub-pixel.

In other words, the sub-pixel 11G included in one pixel Px can be considered as two light-emitting regions g1 and g2.

In the present embodiment, in the display region 100, the light-emitting regions and the coloring layers are arrayed in the following manner based on the array pattern of the light-emitting regions illustrated in FIG. 5 and FIG. 6 and the array pattern of the coloring layers illustrated in FIG. 7, respectively.

FIG. 8A is a diagram illustrating an array of the light-emitting regions and the coloring layers
in the electro-optical device 10 according to the first embodiment.

In order to describe the array of the light-emitting regions and the coloring layers, in the rows with the pixel Px as a unit, first, third, fifth . . . , (m−1)-th rows are odd-numbered rows, and second, fourth, sixth, . . . , m-th rows are even-numbered rows. It can be said that one row with the pixel Px as the unit includes two rows of a first row and a second row adjacent to the first row in the Y direction when the sub-pixel is regarded as a unit.

Also, in the rows with the pixel Px as the unit, first, third, fifth . . . , (n−1)-th columns are odd-numbered columns, and second, fourth, sixth, . . . , n-th columns are even-numbered columns.

In FIG. 8A, a region R simply indicates a position of the light-emitting region r and the coloring layer Cf_r. Similarly, a region G1 simply indicates a position of the light-emitting region g1 and the coloring layer Cf_g, a region G2 simply indicates a position of the light-emitting region g2 and the coloring layer Cf_g, and a region B simply indicates a position of the light-emitting region b and the coloring layer Cf_b.

Note that the actual light-emitting region and the coloring layer are located in a relationship illustrated in FIG. 7 in plan view.

An array pattern serving as a base in the regions R, G1, G2, and B is assumed to be located in an odd-numbered row and odd-numbered column in terms of the pixel.

An array pattern of an odd-numbered row and even-numbered column adjacent to the array pattern of the odd-numbered row and odd-numbered column in the X direction is in a relationship of a line symmetry to the array pattern of the odd-numbered row and odd-numbered column. Specifically, as illustrated in FIG. 8B, the array pattern of the pixel Px1 in the odd-numbered row and odd-numbered column and the array pattern of a pixel Px2 in the odd-numbered row and even-numbered column are in the relationship of the line symmetry with reference to a virtual line Vi1 along the Y direction between the pixel Px1 and the pixel Px2.

In the present embodiment, in the odd-numbered row, the array pattern of the odd-numbered row and odd-numbered column and the array pattern of the odd-numbered row and even-numbered column are alternately repeated along the X direction. In addition, in the present embodiment, the even-numbered row is arrayed in the same manner as the odd-numbered row. That is, the array pattern of the even-numbered row and odd-numbered column is the same as the array pattern of the odd-numbered row and odd-numbered column, and the array pattern of the even-numbered row and even-numbered column are the same as the array pattern of the odd-numbered row and even-numbered column.

Note that, in the array of FIG. 8A, when the data line 14 coupled to the regions G1 and G2 (sub-pixel 11G) is located between the regions G1 and G2, the array of the sub-pixels 11R, 11G, and 11B in the electrical point of view can be considered to be the same as the array illustrated in FIG. 2.

Next, a cross-sectional structure of a main portion of the electro-optical device 10 will be described.

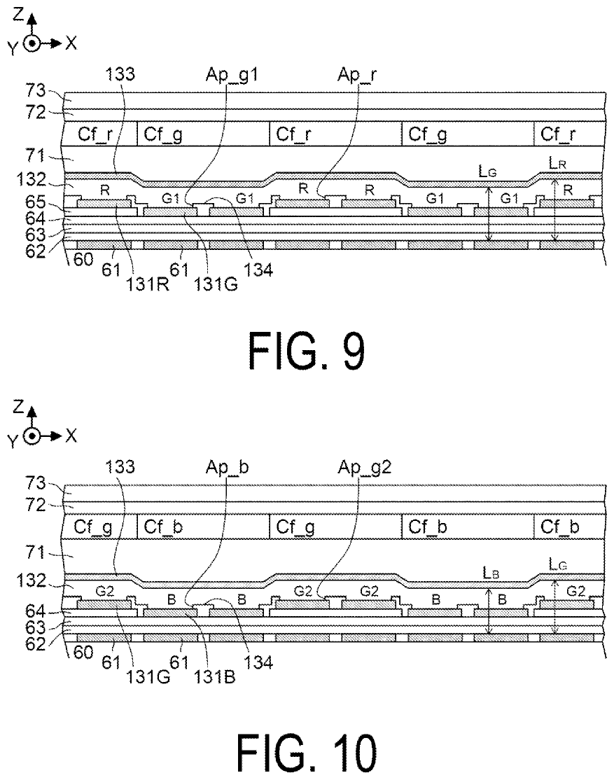

FIG. 9 is a cross-sectional view of the main portion when the electro-optical device 10 is broken at a line C-C′ in FIG. 8A, and FIG. 10 is a cross-sectional view of the main portion when the electro-optical device 10 is broken at a line D-D′ in FIG. 8A.

In the drawings, a substrate 60 is a general term for layers lower than a reflective electrode 61 in the electro-optical device 10 formed of a semiconductor element substrate. The transistors 121 and 122, the scanning lines 12, and data lines 14 are formed on the substrate 60.

The reflective electrode 61 reflects light incident from a direction opposite to the Z direction in the Z direction. As the reflective electrode 61, for example, a conductive layer in which an alloy (AlCu) film of aluminum and copper is stacked on a titanium (Ti) film is used. Note that the reflective electrode 61 is formed by patterning the conductive layer into an island shape in plan view for each pixel electrode 131R, 131G, and 131B.

A reflection enhancing layer 62 having insulating properties and light transmissive properties is provided to cover the reflective electrode 61. A reflection enhancing layer 62 is a layer for enhancing reflection characteristics due to the reflective electrode 61. For example, silicon oxide is used as the reflection enhancing layer 62.

An insulating layer 63 is provided to cover the reflection enhancing layer 62. For example, silicon oxide is used as the insulating layer 63.

A first optical adjustment layer 64 and a second optical adjustment layer 65 are provided in this order to cover the insulating layer 63. However, in the green sub-pixel 11G, the second optical adjustment layer 65 is not provided, and in the blue sub-pixel 11B, the first optical adjustment layer 64 and the second optical adjustment layer 65 are not provided. The first optical adjustment layer 64 and the second optical adjustment layer 65 are insulating layers for adjusting an optical distance in an optical resonator and have light transmissive properties. For example, silicon oxide is used as the first optical adjustment layer 64 and the second optical adjustment layer 65.

Each of the pixel electrodes 131R, 131G, and 131B is formed by patterning a conductive layer having light transmissive properties and conductive properties. The pixel electrode 131R is stacked on the second optical adjustment layer 65, the pixel electrode 131G is stacked on the first optical adjustment layer 64, and the pixel electrode 131B is stacked on the insulating layer 63. For example, indium Tin Oxide (ITO) is used as the conductive layer constituting the pixel electrodes 131R, 131G, and 131B.

The pixel electrode 131R is electrically coupled to the gate electrode of the transistor 121 in the sub-pixel 11R via the contact hole Ct_r, which is not illustrated in the drawing. Similarly, the pixel electrode 131G is electrically coupled to the gate electrode of the transistor 121 in the sub-pixel 11G via the contact hole Ct_g, and the pixel electrode 131B is electrically coupled to the gate electrode of the transistor 121 in the sub-pixel 11B via the contact hole Ct_b.

A separation layer 134 is an insulating film stacked on the insulating layer 63, the first optical adjustment layer 64, the second optical adjustment layer 65, and the pixel electrode 131R, 131G, or 131B, and provided to cover a peripheral edge portion of the pixel electrodes 131R, 131G, and 131B. As illustrated in FIG. 5 in plan view, the separation layer 134 includes the opening portion Ap_r in a pixel portion 110R, includes the opening portions Ap_g1 and Ap_g2 in a pixel portion 110G, and includes the opening portion Ap_b in a pixel portion 110B. For example, silicon oxide is used as the separation layer 134.

The light-emitting layer 132 is stacked on the pixel electrode 131R, 131G, 131B or the separation layer 134. The light-emitting layer 132 is not particularly illustrated, includes a hole injection layer, an organic light-emitting layer, and an electron transport layer, and is common in all the sub-pixels 11R, 11G, and 11B.

The common electrode 133 is a conductive layer having light transmissive properties and reflectivity. The common electrode 133 is provided to cover the light-emitting layer 132 and is common in all the sub-pixels 11R, 11G, and 11B. For example, an alloy of Mg and Ag is used as the common electrode 133.

A sealing layer 71 is an insulating layer having light transmissive properties and is provided to cover the common electrode 133. The sealing layer 71 is provided to prevent moisture and oxygen from entering the light-emitting layer 132 and to flatten an observation surface by eliminating a step.

In a region corresponding to the light-emitting region r, the coloring layer Cf_r is provided in a shape as illustrated in FIG. 7 to cover the sealing layer 71 in plan view. The coloring layer Cf_r is provided by patterning a photosensitive resin including a pigment that selectively transmits red color light using a photolithography technique. Thus, the coloring layer Cf_r has a function of transmitting red color light. Note that the red color light is light including the wavelength range of red. In the present embodiment, the wavelength range of red is 580 nm or more and 700 nm or less.

Similarly, in a region corresponding to the light-emitting regions g1 and g2, the coloring layer Cf_g is provided in a shape as illustrated in FIG. 7 to cover the sealing layer 71 in plan view. The coloring layer Cf_g is provided by patterning a photosensitive resin including a pigment that selectively transmits green color light using a photolithography technique. Thus, the coloring layer Cf_g has a function of transmitting green color light. The green colored light is light including a wavelength range of green. In the present embodiment, the wavelength range of green is 500 nm or more and 580 nm or less.

Similarly, in a region corresponding to the light-emitting region b, the coloring layer Cf_b is provided in a shape as illustrated in FIG. 7 to cover the sealing layer 71 in plan view. The coloring layer Cf_b is provided by patterning a photosensitive resin including a pigment that selectively transmits blue color light using a photolithography technique. Thus, the coloring layer Cf_b has a function of transmitting blue color light. The blue color light is light including a wavelength range of blue. In the present embodiment, the wavelength range of blue is 400 nm or more and 500 nm or less.

Note that, in order to protect the display region 100, a protective glass 73 is bonded to the coloring layers Cf_r, Cf_g, and Cf_b via an adhesive 72.

Speaking of the sub-pixel 11R, the light-emitting layer 132 is a region on the pixel electrode 131R that is not covered by the separation layer 134, that is, a region that is in contact with the pixel electrode 131R, and holes are supplied from a region defined by the opening portion Ap_r to emit white light.

In a portion corresponding to the light-emitting region r in plan view, an optical resonator is formed by the reflective electrode 61 and the common electrode 133 in cross-sectional view, and an optical distance LR between the reflective electrode 61 and the common electrode 133 is adjusted by a film thickness of the reflection enhancing layer 62, the insulating layer 63, the first optical adjustment layer 64, and the second optical adjustment layer 65.

Strictly speaking, the optical distance is a value obtained by multiplying a distance between the reflective electrode 61 and the common electrode 133 by a refractive index of a medium between the reflective electrode 61 and the common electrode 133, but here, it is simply illustrated as a physical distance.

In a portion corresponding to the light-emitting region r, the white light emitted from the light-emitting layer 132 is repeatedly reflected between the reflective electrode 61 and the common electrode 133, and the intensity of light having a wavelength corresponding to the optical distance LR is enhanced. In the present embodiment, as an example, the intensity of light having a wavelength of 610 nm is enhanced in the sub-pixel 11R. The enhanced light passes through the common electrode 133 and is emitted as red light in the Z direction and the like through the coloring layer Cf_r.

In this way, light including a wavelength range of red from the light-emitting region r is emitted in the Z direction or the like.

In a portion corresponding to the light-emitting regions g1 and g2 in plan view, an optical resonator is formed by the reflective electrode 61 and the common electrode 133 in cross-sectional view, and an optical distance LG between the reflective electrode 61 and the common electrode 133 is adjusted by a film thickness of the reflection enhancing layer 62, the insulating layer 63, and the first optical adjustment layer 64. Specifically, in the portion corresponding to the light-emitting regions g1 and g2, since the second optical adjustment layer 65 is not provided between the reflective electrode 61 and the pixel electrode 131G, the optical distance LG is shorter than the optical distance LR by the absence of the second optical adjustment layer 65.

In the portion corresponding to the light-emitting regions g1 and g2, the white light emitted from the light-emitting layer 132 is repeatedly reflected between the reflective electrode 61 and the common electrode 133, and the intensity of light having a wavelength corresponding to the optical distance LG is enhanced. In the present embodiment, as an example, the intensity of light having a wavelength of 540 nm is enhanced in the sub-pixel 11G. The enhanced light passes through the common electrode 133 and is emitted as green light in the Z direction and the like through the coloring layer Cf_g.

In this way, light including a wavelength range of green is emitted in the Z direction and the like from the light-emitting regions g1 and g2.

Similarly, in a portion corresponding to the light-emitting region b in plan view, an optical resonator is formed by the reflective electrode 61 and the common electrode 133 in cross-sectional view, and an optical distance LB between the reflective electrode 61 and the common electrode 133 is adjusted by the reflection enhancing layer 62 and the insulating layer 63.

Specifically, in the portion corresponding to the light-emitting region b, since the first optical adjustment layer 64 is not provided between the reflective electrode 61 and the pixel electrode 131B, the optical distance LB is shorter than the optical distance LG by the absence of the first optical adjustment layer 64.

In a portion corresponding to the light-emitting region b, the white light emitted from the light-emitting layer 132 is repeatedly reflected between the reflective electrode 61 and the common electrode 133, and the intensity of light having a wavelength corresponding to the optical distance LB is enhanced. In the present embodiment, as an example, the intensity of light having a wavelength of 470 nm is enhanced in the sub-pixel 11B. The enhanced light passes through the common electrode 133 and is emitted as green light in the Z direction and the like through the coloring layer Cf_b.

In this way, light including a wavelength range of blue from the light-emitting region b is emitted in the Z direction or the like.

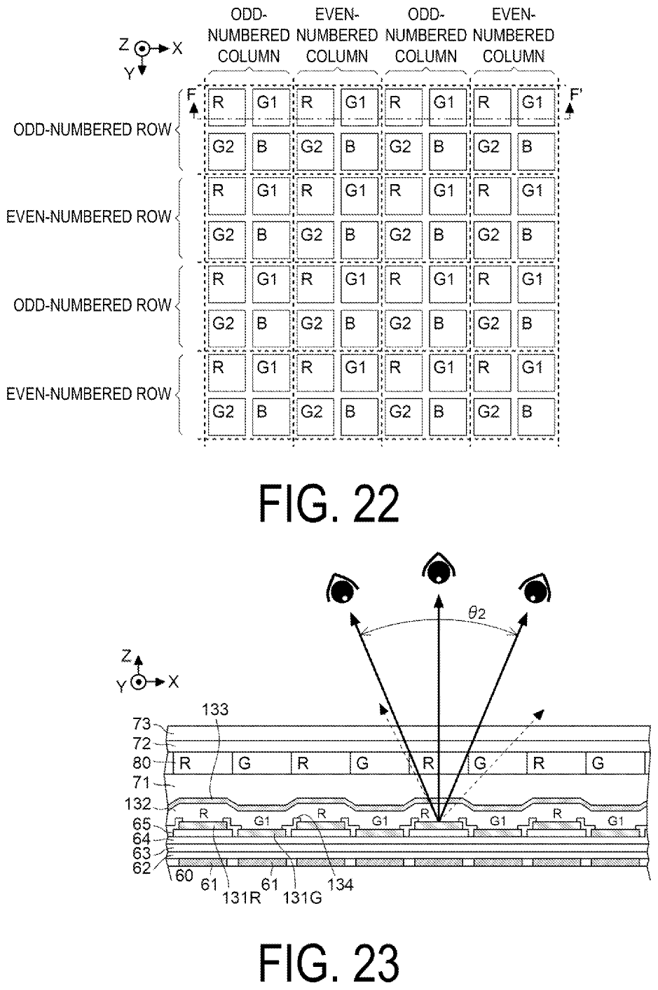

Prior to describing superiority in the first embodiment, a comparative example of the present embodiment will be described. FIG. 22 is a plan view illustrating a light-emitting region according to a first comparative example, and FIG. 23 is a cross-sectional view of a main portion broken at a line F-F′ in FIG. 22.

As illustrated in FIG. 22, in the first comparative example, the array pattern of the light-emitting regions is all common without distinction between the odd-numbered columns and the even-numbered rows.

In the first comparative example, a color of a light-emitting region adjacent to a certain light-emitting region in the X direction or the Y direction is necessarily different from the certain light-emitting region. Thus, in the light-emitting regions adjacent to each other in the X or the Y direction, the colors of the coloring layers are also necessarily different from each other.

Thus, an angle range (visual field angle) of light that passes only through the coloring layer of the corresponding color among light emitted from the light-emitting layer 132 is θ2 in FIG. 23.

Note that light that deviates from the visual field angle θ2 passes through a coloring layer of a different color, as indicated by dashed lines, and thus is not visually recognized as a correct color. Also, in FIG. 23, the visual field angle θ2 for the red color light is illustrated, but other color light such as the green color light and the blue color light have the visual field angle θ2, which is substantially similar to the visual field angle of the red color light.

In contrast to the first comparative example, in the present embodiment, light-emitting regions of a certain color are necessarily adjacent to each other in the X direction. Thus, as illustrated in FIG. 8C, the coloring layers of the same color are coupled to each other in two sub-pixels along the X direction.

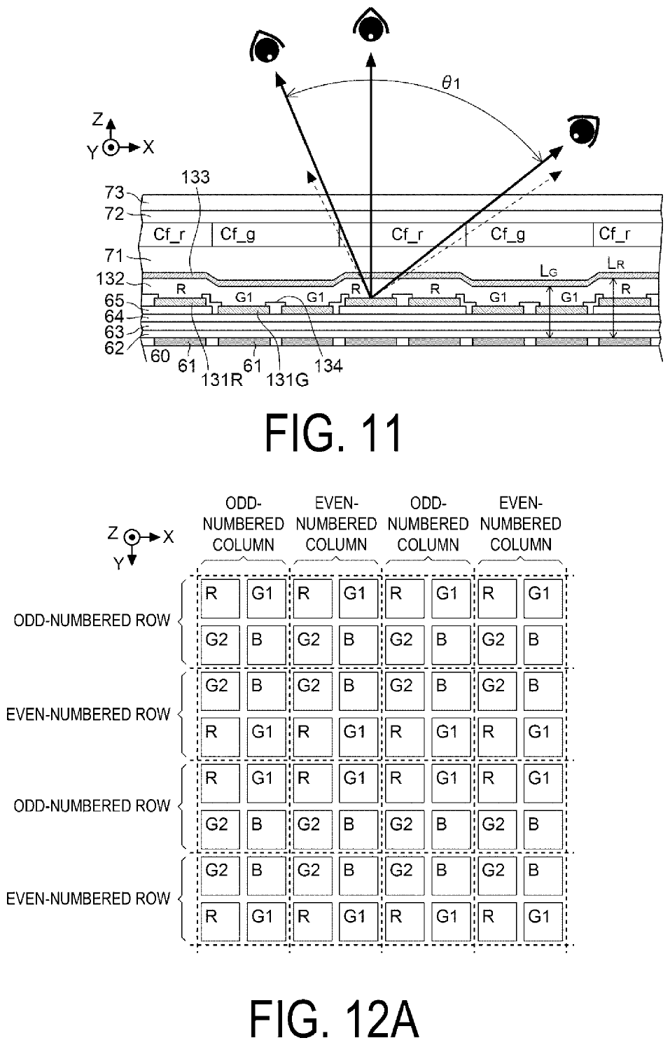

Thus, in the present embodiment, the visual field angle of the light that passes only through the coloring layer of the corresponding color among the light emitted from the light-emitting layer 132 expands to θ1 as illustrated in FIG. 11. Note that, in FIG. 11, the visual field angle θ1 for the red color light is illustrated, but other color light such as green color light and blue color light have the visual field angle θ1, which is substantially similar to the visual field angle of the red color light.

As described above, in the present embodiment, the visual field angles of the red, green, and blue colors are uniform, and the effect of expanding the visual field angle is achieved as compared with the first comparative example.

In addition, in the first comparative example, when a pixel pitch is miniaturized along with miniaturization of the electro-optical device 10, the array pattern of the coloring layers Cf_r, cf_g and Cf_b is also miniaturized. Thus, in the first comparative example, higher accuracy is required for alignment in photolithography at the time of film formation of the coloring layers. In contrast, in the present embodiment, a coloring layer of the same color is shared in two sub-pixels adjacent to each other in the X direction, and thus, in the alignment in the photolithography, the higher accuracy is not required than in the first comparative example.

### First Modified Example of First Embodiment

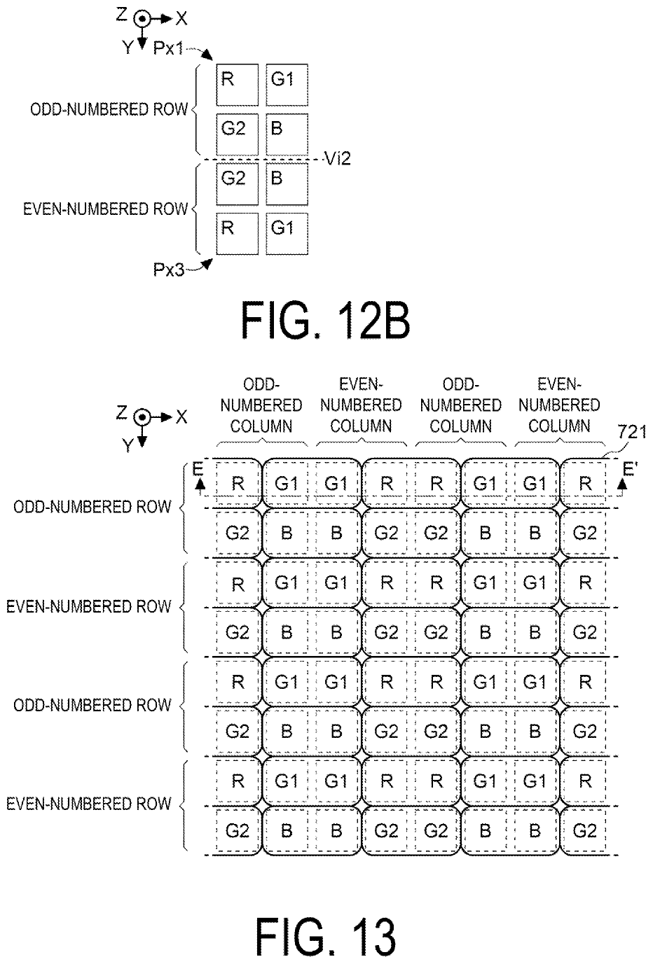

FIG. 12A is a diagram illustrating an array of the light-emitting regions and the coloring layers in the electro-optical device 10 according to a first modified example of the first embodiment.

In the first modified example, an array pattern of the even-numbered row and odd-numbered column adjacent to an array pattern of the odd-numbered row and odd-numbered column in the Y direction is in the relationship of the line symmetry to the array pattern of the odd-numbered row and odd-numbered column. Specifically, as illustrated in FIG. 12B, the array pattern of the pixel Px1 in the odd-numbered row and odd-numbered column and the array pattern of a pixel Px3 in the even-numbered row and odd-numbered column are in the relationship of the line symmetry with reference to a virtual line Vi2 along the X direction between the pixel Px1 and the pixel Px3.

Thus, in the first modified example, light-emitting regions of a certain color are necessarily adjacent to each other in the Y direction, and coloring layers of the same color are continuous in the light-emitting regions adjacent to each other in the Y direction. That is, in the first embodiment, the coloring layers of the same color are coupled to each other in two sub-pixels in the X direction, whereas in the first modified example, the coloring layers are coupled to each other in two sub-pixels in the Y direction.

Thus, also in the first modified example, the visual field angles of the red, green, and blue colors are uniform, and the effect of expanding the visual field angle is achieved as compared with the first comparative example. In addition, in the first modified example, a coloring layer of the same color is shared in two sub-pixels adjacent to each other in the Y direction, and thus, in the alignment in the photolithography, the higher accuracy is not required than in the first comparative example.

### Second Modified Example of First Embodiment

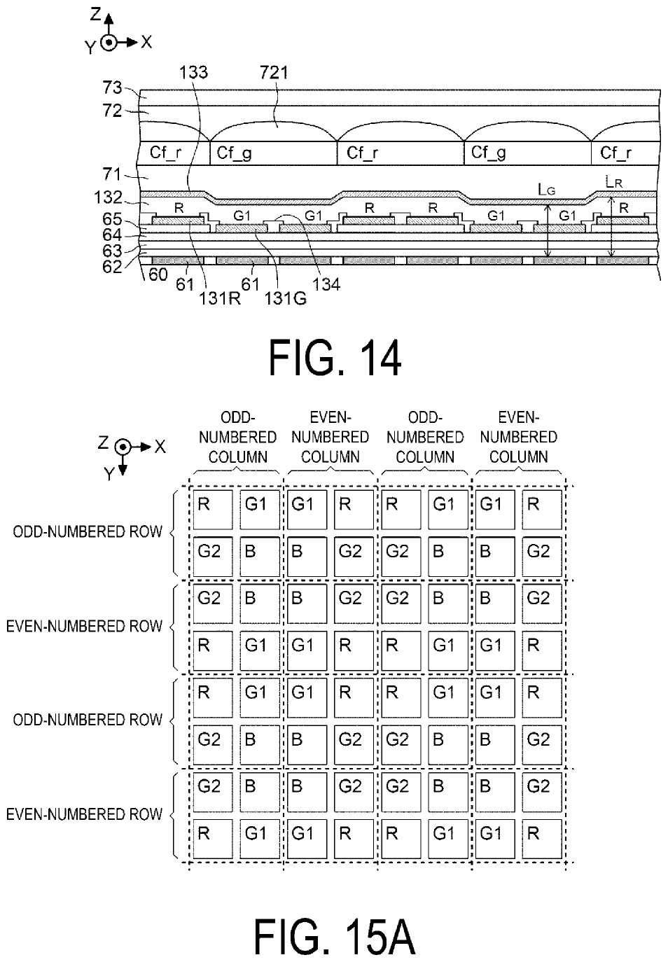

FIG. 13 is a diagram illustrating an array of the light-emitting regions and the coloring layers in the electro-optical device 10 according to a second modified example of the first embodiment.

In the second modified example, an array pattern of the regions R, G1, G2, and B is the same as the array pattern of the first embodiment. However, in the second modified example, one lens 721 is provided corresponding to continuous coloring layers of the same color in the two sub-pixels adjacent to each other.

FIG. 14 is a cross-sectional view of a main portion when the electro-optical device 10 is broken at a line E-E′ in FIG. 13. The lens 721 is stacked on each of the coloring layers Cf_r, Cf_g, and Cf_b, and is provided corresponding to the continuous coloring layers of the same color in the two sub-pixels adjacent to each other. The lens 721 includes a material having transmissive properties and insulating properties, and, for example, a silicon-based inorganic material such as silicon oxide and an organic material such as an acrylic resin are used. According to this second modified example, the emitted light from the light-emitting layer 132 diffuses by the lens 721, and thus the visual field angle characteristics can be further improved.

### Second Embodiment

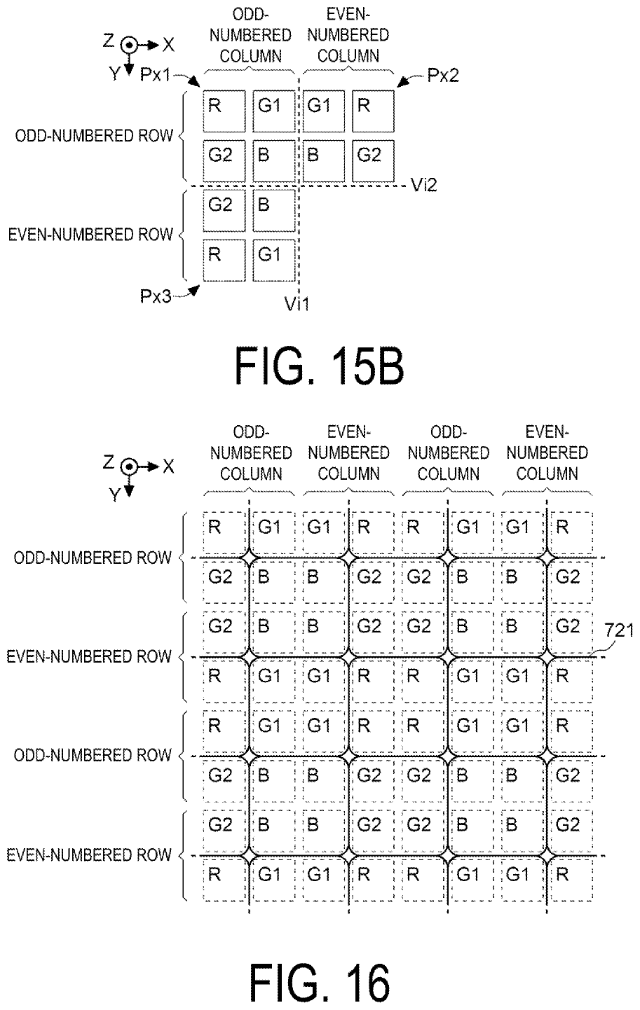

FIG. 15A is a diagram illustrating an array of the light-emitting regions and the coloring layers in the electro-optical device 10 according to the second embodiment.

In the second embodiment, an array pattern of the odd-numbered row and even-numbered column adjacent to an array pattern of the odd-numbered row and odd-numbered column in the X direction is in the relationship of the line symmetry to the array pattern of the odd-numbered row and odd-numbered column, and an array pattern of the even-numbered row and odd-numbered column adjacent to the array pattern of the odd-numbered row and odd-numbered column in the Y direction is in the relationship of the line symmetry to the array pattern of the odd-numbered row and odd-numbered column.

Specifically, as illustrated in FIG. 15B, the array pattern of the pixel Px1 in the odd-numbered row and odd-numbered column and the array pattern of the pixel Px2 in the odd-numbered row and even-numbered column are in the relationship of the line symmetry with reference to a virtual line Vi1 along the Y direction between the pixel Px1 and the pixel Px2. Furthermore, the array pattern of the pixel Px1 and the array pattern of the pixel Px3 in the even-numbered row and odd-numbered column are in the relationship of the line symmetry with reference to the virtual line Vi2 along the X direction between the pixel Px1 and the pixel Px3.

Thus, in the second embodiment, the light-emitting regions of the respective colors are necessarily adjacent to each other in the X direction and the Y direction, and thus four coloring layers in total of the same color with two in the X direction and two in the Y direction are collectively shared in the sub-pixel.

Thus, in the second embodiment, the visual field angles of the red, green, and blue colors are uniform, and the effect of expanding the visual field angle in the longitudinal direction and the transverse direction is achieved.

Additionally, in the second embodiment, as illustrated in FIG. 16, the lens 721 may be provided similarly to the second modified example of the first embodiment. In the second embodiment, the coloring layers of the same color are shared in four sub-pixels in total of 2×2, and thus one lens 721 is provided corresponding to the coloring layers of the same color in the four sub-pixels.

### Third Embodiment

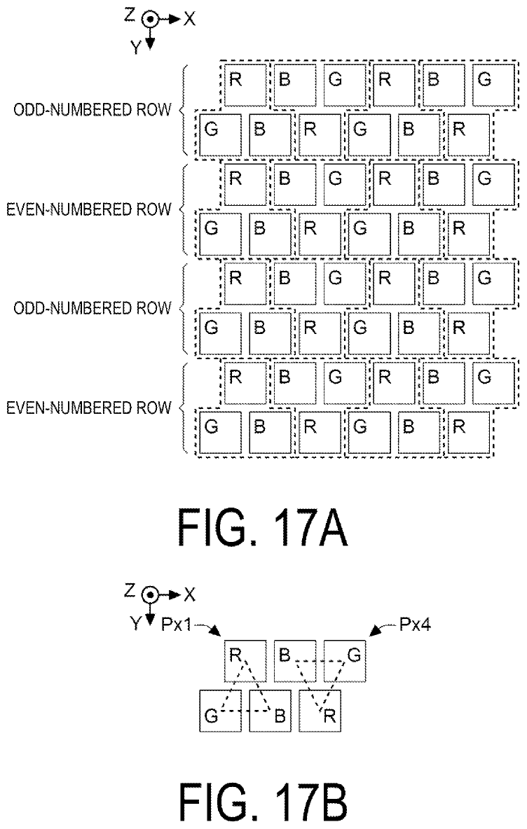

FIG. 17A is a diagram illustrating an array of the light-emitting regions and the coloring layers in the electro-optical device 10 according to a third embodiment. The third embodiment is a so-called a delta array in which the regions R, G and B are arrayed in a triangular shape in plan view, expressing one pixel. In the delta array, two rows of sub-pixels constituting the pixel row are in a relationship of being shifted by a half pitch of the sub-pixel.

In the third embodiment, as illustrated in FIG. 17B, an array pattern of a certain pixel Px1 and an array pattern of a pixel Px4 adjacent to the certain pixel Px1 in the X direction are in a relationship of being rotated by 180 degrees from each other.

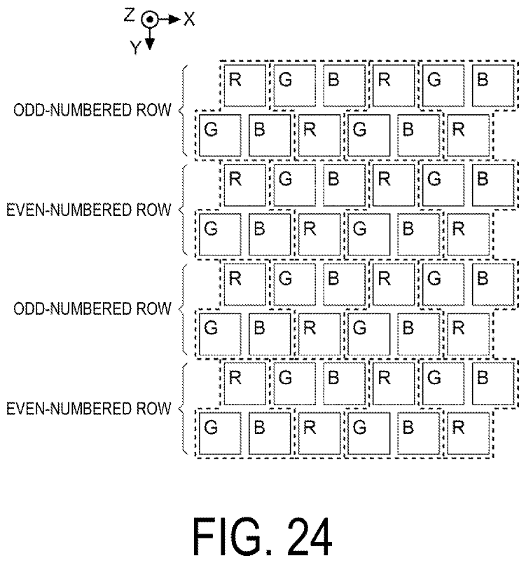

Prior to describing superiority in the third embodiment, a comparative example of the third embodiment will be described. FIG. 24 is a plan view illustrating light-emitting regions and coloring layers according to a second comparative example.

As illustrated in FIG. 24, in the second comparative example, the regions R, G, and B are repeated in this order in the X direction in the two rows of sub-pixels constituting the pixel row, and are in a relationship of being shifted by 1.5 sub-pixels for the region of the same color.

Thus, in the second comparative example, a color of a light-emitting region adjacent to a certain light-emitting region in the X direction or the Y direction is necessarily different from the certain light-emitting region. Thus, in the second comparative example, in the light-emitting regions adjacent to each other in the X or the Y direction, the colors of the coloring layers are necessarily different from each other, and thus the visual field angle is narrower similarly to the first comparative example.

In contrast to the second comparative example, in the third embodiment, each of the region G and the region B among the regions R, G, and B is continuous in the Y direction with overlapping each other by a half pitch of the sub-pixel. Thus, in the third embodiment, the visual field angles among green and blue in a direction overlapping each other by the half pitch are improved as compared with the second comparative example.

### Modified Example of Third Embodiment

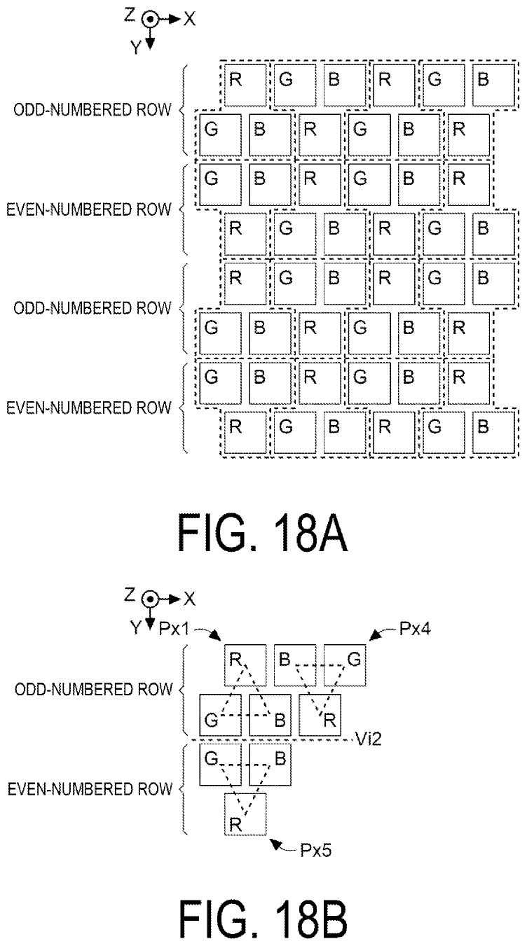

FIG. 18A is a diagram illustrating an array of the light-emitting regions and the coloring layers in the electro-optical device 10 according to a modified example of the third embodiment. Although the present modified example is the delta array similar to the third embodiment, in the present modified example, an array pattern of a certain pixel Px1 and an array pattern of a pixel Px4 adjacent to the certain pixel Px1 in the X direction are in the relationship of being rotated by 180 degrees, and an array pattern of the pixel Px1 and an array pattern of a pixel Px5 adjacent to the pixel Px1 in the Y direction are in the relationship of the line symmetry with reference to the virtual line Vi2 along the X direction between the pixel Px1 and the pixel Px5.

In the present modified example, two of each of the regions R, G and B are continuous in the Y direction. Thus, in the present modified example, the visual field angles of the red, green, and blue colors are uniform and are improved as compared with the second comparative example.

### Fourth Embodiment

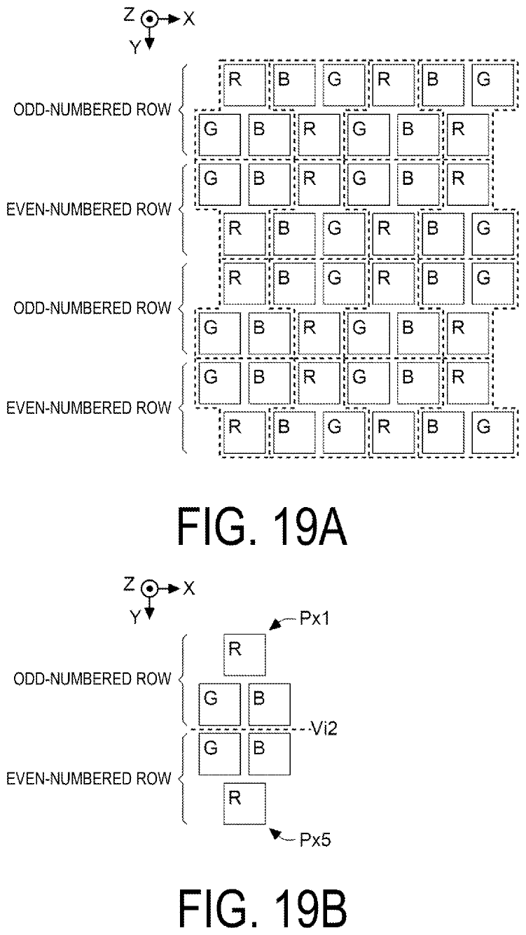

FIG. 19A is a diagram illustrating an array of the light-emitting regions and the coloring layers in the electro-optical device 10 according to a fourth embodiment. The fourth embodiment is a delta array similar to the third embodiment. As illustrated in FIG. 19B, in the fourth embodiment, an array pattern of a certain pixel Px1 and an array pattern of a pixel Px5 adjacent to the pixel Px1 in the Y direction are in the relationship of the line symmetry with reference to the virtual line Vi2 along the X direction between the pixel Px1 and the pixel Px5.

In the fourth embodiment, two of each of the regions R, G and B are continuous in the Y direction with overlapping each other by a half pitch of the sub-pixel. Thus, in the present modified example, the visual field angles of the red, green, and blue colors are uniform and are improved as compared with the second comparative example.

In the fourth embodiment, each of the region G and the region B among the regions R, G, and B is continuous in the Y direction with overlapping each other by a half pitch of the sub-pixel. Also, two regions R are continuous in the Y direction. Thus, in the fourth embodiment, the visual field angles of green and blue are uniform and are improved as compared with the second comparative example.

In the first to fourth embodiments and modified examples of the first to fourth embodiments described above (hereinafter referred to as “embodiments or the like”), various modifications or applications can be made as follows.

In the embodiments or the like described above, the OLED 130 has been illustrated as the example of the light-emitting element, but other light-emitting elements may be used. For example, an LED, a mini LED, and a micro LED may be used as the light-emitting element. Alternatively, rather than the light-emitting element, a liquid crystal element may be used as the display element.

Electronic Device

Next, an electronic device to which the electro-optical device 10 according to the above-described exemplary embodiments is applied will be described. The electro-optical device 10 is suitable for application with a small pixel and high definition display. Thus, a head-mounted display will be described as an example of the electronic device.

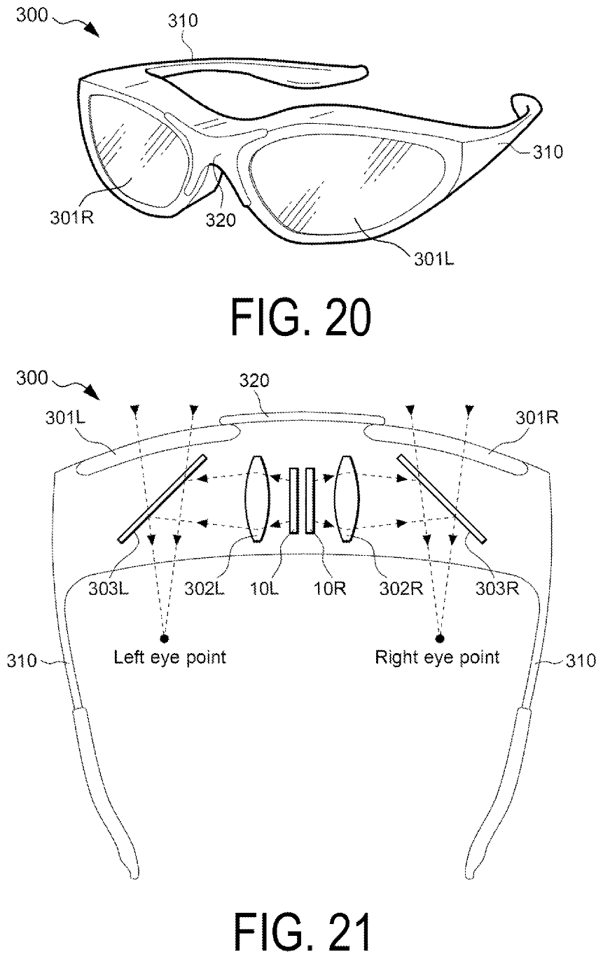

FIG. 20 is a view illustrating an exterior of a head-mounted display, and FIG. 21 is a view illustrating an optical configuration of the head-mounted display.

First, as illustrated in FIG. 20, a head-mounted display 300 includes, in terms of exterior, temples 310, a bridge 320, and lenses 301L and 301R, similar to typical eye glasses. In addition, as illustrated in FIG. 21, in the head-mounted display 300, an electro-optical device 10L for a left eye and an electro-optical device 10R for a right eye are provided in the vicinity of the bridge 320 and on the back side (the lower side in the drawing) of the lenses 301L and 301R.

An image display surface of the electro-optical device 10L is disposed to be on the left side in FIG. 21. Thus, a display image by the electro-optical device 10L is output via an optical lens 302L in a 9-o'clock direction in the drawing. A half mirror 303L reflects the display image by the electro-optical device 10L in a 6-o'clock direction, while the half mirror 303L transmits light incident in a 12-o'clock direction. An image display surface of the electro-optical device 10R is disposed on the right side opposite to the electro-optical device 10L. Thus, the display image by the electro-optical device 10R is output via the optical lens 302R in a 3-o'clock direction in the drawing. A half mirror 303R reflects the display image by the electro-optical device 10R in a 6-o'clock direction, while the half mirror 303R transmits light incident in a 12-o'clock direction.

In this configuration, a wearer of the head-mounted display 300 can observe the display images by the electro-optical devices 10L and 10R in a see-through state in which the display images by the electro-optical devices 10L and 10R overlap the outside.

In addition, in the head-mounted display 300, in the images for both eyes with parallax, an image for a left eye is displayed on the electro-optical device 10L, and an image for a right eye is displayed on the electro-optical device 10R, and thus, it is possible to cause the wearer to sense the displayed images as an image displayed having a depth or a three-dimensional effect.

In addition to the head mounted display 300, the electric apparatus including the electro-optical device 10 can be applied to an electronic viewing finder in a video camera, a lens-exchangeable digital camera, or the like, a mobile information terminal, a wristwatch display, a light valve for a projection type projector, and the like.

Supplementary Description

Preferred aspects of the present disclosure are understood from the above description, as follows. In the following, in order to facilitate understanding of each of the aspects, the reference signs of the drawings are provided in parentheses for convenience, but the present disclosure is not intended to be limited to the illustrated aspects.

An electro-optical device (10) according to one aspect (aspect 1) includes a first pixel (Px1) and a second pixel (Px2, Px3, or Px4) adjacent to the first pixel (Px1) in a first direction (X direction) or a second direction (Y direction), wherein each of the first pixel (Px1) and the second pixel (Px2, Px3, or Px4) includes a sub-pixel (11R) that emits first color light beam, a sub-pixel (11G) that emits second color light beam, and a sub-pixel (11B) that emits third color light beam, and a first pattern which is an arrangement pattern of a plurality of sub-pixels included in the first pixel (Px1) in plan view and a second pattern which is an arrangement pattern of a plurality of sub-pixels included in the second pixel (Px2, Px3, or Px4) in plan view are in a relationship of a line symmetry to each other with reference to a virtual line (Vi1 or Vi2) between the first pixel (Px1) and the second pixel (Px2, Px3, or Px4) or in a relationship of being rotated by 180 degrees from each other.

According to the aspect 1, the visual field angle can be expanded while reducing a deviation of the visual field angle characteristics between the first color light beam, the second color light beam, and the third color light beam.

In the electro-optical device (10) according to a specific aspect 2 of the aspect 1, the second pixel (Px2) is adjacent to the first pixel (Px1) along the first direction (X direction), a third pixel (Px3) adjacent to the first pixel (Px1) in the second direction (Y direction) is included, the third pixel (Px3) includes the sub-pixel (11R) that emits the first color light beam, the sub-pixel (11G) that emits the second color light beam, and the sub-pixel (11B) that emits the third color light beam, the first pattern and the second pattern are in the relationship of the line symmetry to each other with reference to a first virtual line (Vi1) between the first pixel (Px1) and the second pixel (Px2), and the first pattern and a third pattern which is an arrangement pattern of a plurality of the sub-pixels included in the third pixel (Px3) in plan view are in the relationship of the line symmetry to each other with reference to a second virtual line (Vi2) between the first pixel (Px1) and the third pixel (Px3).

According to the aspect 2, the visual field angle can be further expanded as compared with the aspect 1.

In the electro-optical device (10) according to a specific aspect 3 of the aspect 1, the second pixel (Px4) is adjacent to the first pixel (Px1) in the first direction (X direction), a third pixel (Px5) adjacent to the first pixel (Px1) in the second direction (Y direction) is included, the third pixel (Px5) includes the sub-pixel (11R) that emits the first color light beam, the sub-pixel (11G) that emits the second color light beam, and the sub-pixel (11B) that emits the third color light beam, the first pattern and the second pattern are in the relationship of being rotated by 180 degrees from each other, and the first pattern and a third pattern which is an arrangement pattern of a plurality of the sub-pixels included in the third pixel (Px5) in plan view are in the relationship of the line symmetry to each other with reference to a virtual line (Vi2) between the first pixel (Px1) and the third pixel (Px5).

According to the aspect 3, the visual field angle can be expanded while reducing a deviation of the visual field angle characteristics between the first color light beam, the second color light beam, and the third color light beam.

In the electro-optical device (10) according to an aspect 4 of any of the aspects 1 to 3, a first coloring layer (Cf_r) corresponding to the first color light beam is provided in the sub-pixel (11R) that emits the first color light beam in the first pixel (Px1) and the sub-pixel (11R) that emits the first color light beam in the second pixel (Px2, Px3, or Px4), a second coloring layer (Cf_g) corresponding to the second color light beam is provided in the sub-pixel (11G) that emits the second color light beam in the first pixel (Px1) and the sub-pixel (11G) that emits the second color light beam in the second pixel (Px2, Px3, or Px4), and a third coloring layer (Cf_b) corresponding to the third color light beam is provided in the sub-pixel (11B) that emits the third color light beam in the first pixel (Px1) and the sub-pixel (11B) that emits the third color light beam in the second pixel (Px2, Px3, or Px4).

In the electro-optical device (10) according to an specific aspect 5 of the aspect 4, each of the sub-pixel (11R) that emits the first color light beam, the sub-pixel (11G) that emits the second color light beam, and the sub-pixel (11B) that emits the third color light beam includes a light-emitting element (130) in which a light-emitting layer (133) is sandwiched between a respective one of pixel electrodes (131R, 131G, and 131B) and a common electrode (133), and a sealing layer (71) is provided between the light-emitting element (130) and the first coloring layer (Cf_r), the second coloring layer (cf_g), and the third coloring layer (Cf_b).

In the electro-optical device (10) according to a specific aspect 6 of the aspect 5, the pixel electrodes (131R, 131G, and 131B) are provided between a reflective electrode (61) and the common electrode (133), and optical distance (LR, LG, and LB) between the reflective electrode (61) and the common electrode (131) is different in a first sub-pixel (11R), a second sub-pixel (11G), and a third sub-pixel (11B).

The electro-optical device (10) according to a specific aspect 7 of any of the aspects 1 to 6 includes one lens (721) for two or four sub-pixels which are adjacent to each other in plan view and emit the same color light beam.

In an electro-optical device (10) according to another aspect (aspect 8), a plurality of sub-pixels provided in a first row include a sub-pixel (11R) that emits first color light beam and a sub-pixel (11G) that emits second color light beam. a plurality of sub-pixels provided in a second row adjacent to the first row include the sub-pixel (11R) that emits the first color light beam and a sub-pixel (11B) that emits third color light beam, in the first row, a plurality of the sub-pixels (11R) that emit the first color light beam include two sub-pixels arranged side by side, and a plurality of the sub-pixels (11G) that emit the second color light beam include two sub-pixels arranged side by side, and in the second row, the plurality of sub-pixels (11R) that emit the first color light beam include two sub-pixels arranged side by side, and a plurality of the sub-pixels (11B) that emit the third color light beam include two sub-pixels arranged side by side.

According to the aspect 8, the visual field angle can be expanded while reducing the deviation of the visual field angle characteristics between the first color light beam, the second color light beam, and the third color light beam.

In addition, an electronic device (300) according to an aspect 9 includes an electro-optical device (10) according to any of the aspects 1 to 8.

What is claimed is:

1. An electro-optical device, comprising:
a first pixel; and
a second pixel adjacent to the first pixel in a first direction or a second direction, wherein
each of the first pixel and the second pixel includes
a sub-pixel configured to emit a first color light beam,
a sub-pixel configured to emit a second color light beam, and
a sub-pixel configured to emit a third color light beam, and
a first pattern that is an arrangement pattern, in plan view, of a plurality of the sub-pixels included in the first pixel and
a second pattern that is an arrangement pattern, in plan view, of a plurality of the sub-pixels included in the second pixel
are in a relationship of a line symmetry to each other with reference to a virtual line between the first pixel and the second pixel or in a relationship of being rotated by 180 degrees from each other.

2. The electro-optical device according to claim 1, wherein
the second pixel is adjacent to the first pixel in the first direction,
a third pixel adjacent to the first pixel in the second direction is included,
the third pixel including
a sub-pixel configured to emit a first color light beam,
a sub-pixel configured to emit a second color light beam, and
a sub-pixel configured to emit a third color light beam,
the first pattern and the second pattern are in a relationship of a line symmetry to each other with reference to a first virtual line between the first pixel and the second pixel, and
the first pattern and a third pattern that is an arrangement pattern, in plan view, of a plurality of the sub-pixels included in the third pixel are in a relationship of a line symmetry to each other with reference to a second virtual line between the first pixel and the third pixel.

3. The electro-optical device according to claim 1, wherein
the second pixel is adjacent to the first pixel along the first direction,
a third pixel adjacent to the first pixel in the second direction is included,
the third pixel including
a sub-pixel configured to emit a first color light beam,
a sub-pixel configured to emit a second color light beam, and
a sub-pixel configured to emit a third color light beam,
the first pattern and the second pattern are in a relationship of being rotated by 180 degrees from each other, and
the first pattern and a third pattern that is an arrangement pattern, in plan view, of a plurality of the sub-pixels included in the third pixel are in a relationship of a line symmetry to each other with reference to a virtual line between the first pixel and the third pixel.

4. The electro-optical device according to claim 1, wherein
the sub-pixel configured to emit the first color light beam in the first pixel and the sub-pixel configured to emit the first color light beam in the second pixel include a first coloring layer corresponding to the first color light beam,
the sub-pixel configured to emit the second color light beam in the first pixel and the sub-pixel configured to emit the second color light beam in the second pixel include a second coloring layer corresponding to the second color light beam, and
the sub-pixel configured to emit the third color light beam in the first pixel and the sub-pixel configured to emit the third color light beam in the second pixel include a third coloring layer corresponding to the third color light beam.

5. The electro-optical device according to claim 4, wherein
each of the sub-pixel configured to emit the first color light beam, the sub-pixel configured to emit the second color light beam, and the sub-pixel configured to emit the third color light beam includes a light-emitting element, the light-emitting element including a light-emitting layer sandwiched between a pixel electrode and a common electrode, and
a sealing layer is provided between the light-emitting element and the first coloring layer, the second coloring layer, and the third coloring layer.

6. The electro-optical device according to claim 5, wherein
the pixel electrode is provided between a reflective electrode and the common electrode, and
an optical distance between the reflective electrode and the common electrode is different for the first sub-pixel, the second sub-pixel, and the third sub-pixel.

7. The electro-optical device according to claim 1, comprising
one lens for two or four sub-pixels, the two or four sub-pixels being adjacent to each other in plan view and configured to emit a same color light beam.

8. An electro-optical device, wherein
a plurality of sub-pixels provided in a first row include a sub-pixel configured to emit a first color light beam, and a sub-pixel configured to emit a second color light beam,
a plurality of sub-pixels provided in a second row adjacent to the first row include the sub-pixel configured to emit the first color light beam, and a sub-pixel configured to emit a third color light beam,
in the first row, a plurality of the sub-pixels configured to emit the first color light beam include two sub-pixels arranged side by side, and a plurality of the sub-pixels configured to emit the second color light beam include two sub-pixels arranged side by side, and
in the second row, the plurality of sub-pixels configured to emit the first color light beam include two sub-pixels arranged side by side, and a plurality of the sub-pixels configured to emit the third color light beam include two sub-pixels arranged side by side.

9. An electronic device comprising the electro-optical device according to claim 1.
